(19) United States
(12) Patent Application Publication
(10) Pub. No.: US 2018/0110146 A1
(43) Pub. Date: Apr. 19, 2018

(54) ECU HOUSING AND COVER FOR USE THEREIN

(71) Applicant: TRW Limited, Solihull (GB)

(72) Inventors: David Jonathan Coles, Birmingham (GB); Stuart Leigh Bland, Birmingham (GB)

(73) Assignee: TRW Limited, Solihull (GB)

(21) Appl. No.: 15/730,882

(22) Filed: Oct. 12, 2017

(30) Foreign Application Priority Data
Oct. 13, 2016 (GB) 1617397.3

(51) Int. Cl. H05K 5/06; B60R 16/023; H05K 5/00

(52) U.S. Cl. CPC H05K 5/065; H05K 5/0013; B60R 16/0239

(57) ABSTRACT

A housing for a vehicle electronic control unit. The housing comprises a mounting part and a removable cover which is removably attachable to the mounting part. Thus, the housing defines a chamber for the receipt of the vehicle electronic control unit. The removable cover includes an inner shell and an outer shell, the outer shell being formed of a rigid material and forming an external wall of the housing that provides a primary barrier for the prevention or limitation of water ingress into the chamber. The inner shell extends over substantially the entire inner extent of the outer shell and is constructed of a compliant material which, in the event of deformation or damage to the integrity of the outer shell, provides a secondary barrier for the prevention or limitation of water ingress into the chamber.

### CROSS-REFERENCE TO RELATED APPLICATIONS

This application claims priority to Great Britain Patent Application No. 1617397.3, filed 13 Oct. 2016, the disclosures of which are incorporated herein by reference in entirety.

### BACKGROUND OF THE INVENTION

The present invention relates to improvements to a housing for vehicle electronic control units and more specifically to the prevention of water ingress through said housings. The invention also relates to a cover for use in the creation of a waterproof housing for a vehicle electronic control unit.

Modern vehicles require a number of electronic control units (ECUs) in order to function correctly. These ECUs are associated with different systems such as the power steering system, engine control system, and the braking system. Each ECU is therefore required to be in reasonably close proximity to such systems, resulting in them being exposed to water and other potentially hazardous conditions.

ECUs must therefore be protected from such hazards by a protective housing. One of the main functions of the ECU housing is to prevent water damage to the sensitive electronic components inside. However, when combined with other hazardous conditions, this can be difficult to achieve. Hazardous conditions can include extreme temperatures, corrosive substances, and impacts from foreign objects such as stones. If a housing becomes damaged, allowing water to leak onto the ECU itself, this can result in inoperative systems and can require expensive repairs or replacement of the ECU itself.

Known ECU housings generally comprise a mounting part on which the ECU is mounted and a removable cover which is placed over the top and forms a seal with the mounting part. A separate seal element can also be included, if necessary. The removable cover and optionally the mounting part are generally formed of a metal or structurally rigid plastics material which is waterproof and provides some protection from corrosion and impacts. However, over time, and due to repeated impacts or deterioration of the housing material due to chemical or environmental factors, the housing can fail, allowing water ingress. The applicant therefore seeks to ameliorate these issues.

### BRIEF SUMMARY OF THE INVENTION

In accordance with a first aspect of the invention, there is provided a housing for a vehicle electronic control unit, the housing comprising a mounting part and a removable cover which is removably attachable to the mounting part, the housing defining a chamber for the receipt of the vehicle electronic control unit,

the mounting part providing a mount for the electronic control unit,

the removable cover including an inner shell and an outer shell, the outer shell being formed of a rigid material and forming an external wall of the housing that provides a primary barrier for the prevention or limitation of water ingress into the chamber, the inner shell extending over substantially an entire inner extent of the outer shell and being constructed of a compliant material which, in the event of deformation or damage to the integrity of the outer shell, provides a secondary barrier for the prevention or limitation of water ingress into the chamber.

The secondary barrier provided by the inner shell ensures that the ECU is not susceptible to water damage in the event that the outer shell is breached. Thus, protection is maintained. As the outer shell is formed of a rigid material, even when damaged such that it is not waterproof, it may still provide protection from further impact, meaning that the housing will continue to provide effective protection to the ECU and that therefore the ECU will continue to operate without issue, at least until a repair can be effected. It may also be possible for breach of the outer shell or any other damage to result in limp-home or limp-aside functionality being activated, in order to allow continuous operation.

The outer shell may form a rigid structure. The rigid structure may form a continuous surface over an outer extent of the outer shell.

The rigid structure may define a vertical and/or lateral extent of the chamber. The vertical extent of the chamber may be defined by at least one upper wall of the outer shell and the lateral extent of the chamber may be defined by at least one side wall of the outer shell.

The removable cover may have an open face which is closable by the mounting part. The open face may be defined by lowermost edges of the at least one side wall.

The housing may include a seal element, interposable between the mounting part and removable cover for forming or enhancing a waterproof or substantially waterproof seal therebetween.

The seal element may be positioned between the lowermost edges and the mounting part. Additionally or alternatively, a seal element may be provided adjacent to a vertical face, for instance by the provision of an O-ring seal. In another possibility, compression of a part of the inner shell may be used to provide a seal rather than use of a separate sealing element.

The removable cover may be mountable to the mounting part by fastening means. Fastening means may include one or more fasteners. The or each fastener may include a clip, latch, or screw-fixing. Furthermore, the or each fastener may include a latching part and a detent part, the latching part being resiliently flexible for latching onto the detent part. Alternatively, the fastening means could sealants or other chemical or mechanical joints.

The outer shell may comprise a rigid plastics material.

The inner shell may comprise a non-brittle material. The inner shell may comprise at least one of a liquid silicone rubber and a thermoplastic elastomer.

The inner shell may comprise a layer in contact with the outer shell over substantially the entire extent of the inner shell. For example, the inner shell may be adhered or otherwise affixed to the outer shell, for instance by twin-shot moulding or an equivalent technique.

The inner shell may comprise a layer which is separated from the outer shell over substantially the entire extent of the inner shell. This can allow for some deformation of the outer shell without deformation of the inner shell. It can also allow for some thermal insulation of the chamber within the housing.

The inner shell may be compliant to the outer shell. The compliance of the inner shell will therefore allow the inner shell to deform with the outer shell whilst still maintaining protection against water ingress.

The inner shell may maintain integrity under a predetermined impact loading of the outer shell.

The mounting part may be attached to, or integrally formed with, a part of a vehicle. The part of the vehicle may provide support and/or protection against impacts to the mounting part.

Other advantages of this invention will become apparent to those skilled in the art from the following detailed description of the preferred embodiments, when read in light of the accompanying drawings.

### BRIEF DESCRIPTION OF THE DRAWINGS

FIG. 1 is a diagrammatic view of a first embodiment of an ECU housing in accordance with the invention;

FIG. 2 is a perspective view of the cover of the ECU housing of FIG. 1, shown in partial cross-section; and

FIG. 3 is a diagrammatic view of a second embodiment of an ECU housing in accordance with the invention.

### DETAILED DESCRIPTION OF THE INVENTION

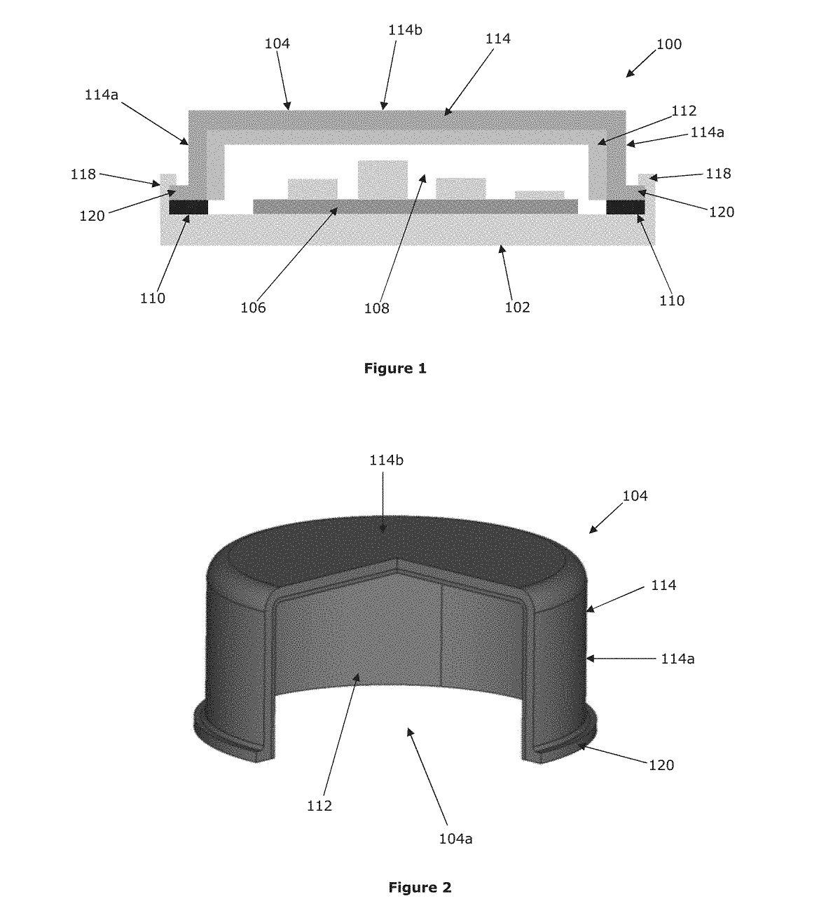

Referring firstly to FIGS. 1 and 2, there is depicted a waterproof ECU housing 100 in accordance with the invention. The housing 100 is formed of a mounting part 102 and a removable cover 104. The mounting part 102 provides a mount for the ECU 106 which is supported thereon, and is, in use, affixed to a part of a vehicle (not shown). The part of the vehicle to which the mounting part could be affixed might include a motor, gearbox, structural component of the vehicle, or a structure including other electronics. Other possibilities will also be clear to the skilled person. The mounting part 102 and/or removable cover 104 may also include apertures (not shown) through which cables or connectors may lead or be received in order to provide power to the ECU 106 and allow the ECU 106 to communicate with external components. Where necessary, these apertures may include further seals to ensure protection against leakage.

The ECU 106, although shown as a simple PCB assembly, could also be a more complex unit. For example, the ECU could include leadframes or connectors, or any other sort of computing unit that is common within the art.

The ECU 106 is enclosed within a chamber 108 formed by the mounting part 102 and the removable cover 104. The mounting part 102 and removable cover 104 are each formed of water-impermeable materials, in order to protect the ECU 106 from damage due to water ingress. Finally, a seal element 110 is positioned between the mounting part 102 and the removable cover 104, ensuring that the chamber 108 is watertight.

Although the described embodiment includes a mounting part and removable cover that are each formed of water-impermeable materials, it may be that the mounting part is not required to be water-impermeable. For example, the mounting part may itself form part of a more expansive structure in which the watertight aspect is provided by other components and not necessarily the mounting part.

In order to provide improved protection over known ECU housings, the removable cover 104 has a dual-shell structure and comprises an inner shell 112 and an outer shell 114. The outer shell 114 provides a primary barrier against hazards such as impacts from foreign objects, which may, for instance, be thrown up from the road, and water ingress. For this reason, the outer shell 114 is formed of a rigid material such as thermoset plastics, such that it may withstand these hazards.

As the outer shell forms a rigid structure, it may define the shape of the chamber 108 within. Therefore, in the present embodiment, a side wall 114a of the outer shell 114 defines a lateral extent of the chamber 108 whilst an upper wall 114b of the outer shell 114 defines a vertical extent of the chamber 108. Although only a single upper wall 114b and single side wall 114a are included in the present embodiment, the invention is not limited to such a shape and a greater number of upper walls and side walls may be included in order to form a more complex three-dimensional shape.

In the present embodiment, the rigid structure forms a continuous surface over an outer extent of the outer shell 114. Thus, protection is provided from impacts and the rigid structure also provides waterproofing and other protection.

The side walls 114a therefore include lower edges 114c which define an open face 104a of the removable cover 104. This open face 104a can then be sealed by positioning the removable cover 104 on the mounting part 102, ensuring that the housing 100 is watertight.

The inner shell 112 provides a secondary barrier in the event of any one of a number of failure modes of the outer shell 114. Such failure modes may include mechanical fatigue through repeated impact resulting in cracking, severe impact and/or thermal stress resulting in fracture of the material, or weakening of the outer shell 114 due to chemical corrosion, amongst other things.

In the case of known housings, the failure of the single layer removable cover would result in the watertight nature of the housing being compromised and thus allowing water damage to the ECU. Therefore, the inner shell 112 of the present invention is located such that it forms a secondary barrier between the chamber 108 containing the ECU 106 and the outer shell 114, ensuring that any breach of the outer shell 114 does not allow water into the chamber 108.

The inner shell 112 must provide protection against the ingress of water. However, it may also provide enhanced protection against chemical corrosion or weakening caused by oils, salt water, or other fluids which it may encounter, in use.

In the first embodiment, as shown in FIGS. 1 and 2, the inner shell 112 is formed as a layer that is adhered to the outer shell 114. As such, there is no gap between the inner shell 112 and the outer shell 114. In the event of an impact which fractures or deforms the outer shell 114, it is therefore necessary that the inner shell 112 is able to adapt to its new shape without any failure of its own. For this reason, the inner shell 112 may comprise a material such as a liquid silicone rubber or a thermoplastic elastomer. Such materials allow the inner shell 112 to retain integrity even when deformed. Whilst such a material would not be capable of providing the impact protection of the outer shell 114, it is hoped that the outer shell 114, even when fractured, would still retain its original structure enough to protect from further impact damage.

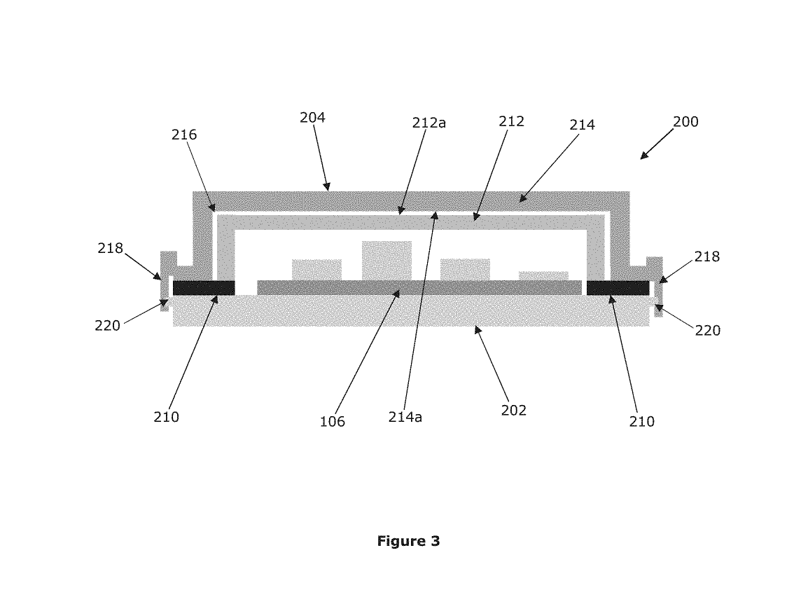

A second embodiment is shown in FIG. 3. Identical or similar features are labelled with identical or similar reference numbers, where applicable.

Alternatively, as in the housing 200 of FIG. 3, the removable cover 204 may comprise an inner shell 212 which is separated from the outer shell 214. By separated, it is meant that there is a gap 216 between an outer surface 212a of the inner shell 212 and an inner surface 214a of the outer shell 214, at least over a majority of the respective surfaces 212a, 214a. Advantageously, the gap 216 between the inner shell 212 and outer shell 214 may allow some deformation of the outer shell 214 before any deformation is caused to the inner shell 212. Furthermore, it may allow for some limited thermal insulation of the ECU 106.

Where the inner shell 212 is separated from the outer shell 214, it may be necessary to extend the seal element 210, as shown in FIG. 3. Therefore, the seal element 210 extends between not only the mounting part 202 and the outer shell 214 but also the mounting part 202 and the inner shell 212. This may provide additional protection against water ingress. It may also be possible to connect the inner shell 212 to the outer shell 214 at or near to the mounting part 202, in order that extending the seal element 210 is not necessary.

If additional support for the inner shell is required, struts or other connection may be used at points within the removable cover to provide attachment between the outer shell and inner shell. Where this is the case, the inner shell is still considered to be separated from or substantially separated from the outer shell.

One method of connecting the removable cover 204 to the mounting part 202 is shown in FIG. 3. Here, two latching parts 218 are used which may be formed integrally with the removable cover 204 and attach to corresponding detent parts 220 on the mounting part 202. The latching parts 218, which are resiliently flexible so as to enable a press-fit connection between themselves and the detent parts 220 allow the removable cover 204 to be fitted quickly to the mounting part 202, whilst also enabling easy removal in the case where repair or replacement of the ECU 106 is required. The connection could also be positioned the other way round, with the latching parts 118 on the mounting part 102 and the detent parts 120 on the removable cover 104, as in FIG. 1. Alternative methods of connection of the mounting part and removable cover may also be used. For example, the removable cover may include screw holes which allow screw connection to the mounting part, or any other form of releasable fastener may be used. Other fastening means may also be used, for example sealants or chemical or mechanical fastening methods,

The mounting part may provide mounting points which allow the ECU to be clipped, screwed, adhered, or otherwise affixed to the mounting part. This ensures that the ECU is held in a fixed position within the chamber, thus preventing damage.

Although specific materials have been mentioned for the above components, it is not intended to limit the scope of the invention to those particular materials. Any other materials which have the desired characteristics may also be used. Such materials will be known to those skilled in the art and may have additional properties. For example, it may be desirable for the inner shell to include electromagnetic shielding from conducted or radiated emissions or other properties by, for example, forming it from multiple materials.

Some features have been described in relation to one embodiment and not the other. However, each feature may be used in either embodiment or in combination in further embodiments, unless there are specific restrictions which prevent the combination of features.

In accordance with the provisions of the patent statutes, the principle and mode of operation of this invention have been explained and illustrated in its preferred embodiments. However, it must be understood that this invention may be practiced otherwise than as specifically explained and illustrated without departing from its spirit or scope.

What is claimed is:

1. A housing for a vehicle electronic control unit, the housing comprising a mounting part and a removable cover which is removably attachable to the mounting part, the housing defining a chamber for the receipt of the vehicle electronic control unit,
the mounting part providing a mount for the electronic control unit,
the removable cover including an inner shell and an outer shell, the outer shell being formed of a rigid material and forming an external wall of the housing that provides a primary barrier for the prevention or limitation of water ingress into the chamber, the inner shell extending over substantially an entire inner extent of the outer shell and being constructed of a compliant material which, in the event of deformation or damage to the integrity of the outer shell, provides a secondary barrier for the prevention or limitation of water ingress into the chamber.

2. The housing as claimed in claim 1, the outer shell forming a rigid structure.

3. The housing as claimed in claim 2, the rigid structure forming a continuous surface over an outer extent of the outer shell.

4. The housing as claimed in claim 2, the rigid structure defining a vertical extent of the chamber.

5. The housing as claimed in claim 4, the vertical extent being defined by at least one upper wall of the outer shell.

6. The housing as claimed in claim 2, the rigid structure defining a lateral extent of the chamber.

7. The housing as claimed in claim 6, the lateral extent being defined by at least one side wall of the outer shell.

8. The housing as claimed in claim 1, the removable cover having an open face which is closable by the mounting part.

9. The housing as claimed in claim 1, the lateral extent being defined by at least one side wall of the outer shell, the removable cover having an open face which is closable by the mounting part and the open face being defined by lowermost edges of the at least one side wall.

10. The housing as claimed in claim 1, the housing including a seal element, interposable between the mounting part and the removable cover for forming or enhancing a waterproof or substantially waterproof seal therebetween.

11. The housing as claimed in claim 10, the seal being positioned between the lowermost edges and the mounting part.

12. The housing as claimed in claim 1, the removable cover being releasably mountable to the mounting part.

13. The housing as claimed in claim 1, the outer shell comprising a rigid plastics material.

14. The housing as claimed in claim 1, the inner shell comprising a non-brittle material.

15. The housing as claimed in claim 1, the inner shell comprising a layer in contact with the outer shell over substantially the entire extent of the inner shell.

16. The housing as claimed in claim 1, the inner shell comprising a layer which is separated from the outer shell over substantially the entire extent of the inner shell.

17. The housing as claimed in claim 1, the inner shell being compliant to the outer shell.

18. The housing as claimed in claim 1, the inner shell maintaining integrity under a predetermined impact loading of the outer shell.

19. The housing as claimed in claim 1, the mounting part being attached to, or integrally formed with, a part of a vehicle.
